(19) United States
(12) Patent Application Publication
(10) Pub. No.: US 2010/0244145 A1
(43) Pub. Date: Sep. 30, 2010

(54) Semiconductor memory device using hot electron injection

(75) Inventor: Katsutoshi Saeki, Miyagi (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/659,780

(22) Filed: Mar. 22, 2010

(30) Foreign Application Priority Data
Mar. 26, 2009 (JP) 2009-077310

(51) Int. Cl. H01L 27/088

(52) U.S. Cl. 257/392; 257/E27.061

(57) ABSTRACT

A semiconductor memory device has a low-resistivity semiconductor substrate on which a higher-resistivity semiconductor layer of the same conductivity type is formed. Memory cell transistors are formed in the semiconductor layer. A diffusion region, also of the same conductivity type, is formed below the memory cell transistors. The resistivity of the diffusion region is lower than the resistivity of the semiconductor layer. In the programming of data into the memory cell transistors by hot electron injection, the diffusion region reduces the voltage drop due to current flow from the part of the semiconductor layer near the memory cell transistors into the semiconductor substrate, thereby reducing unwanted elevation of the potential of the semiconductor layer.

### BACKGROUND OF THE INVENTION

1. Field of the Invention

The present invention relates to a semiconductor memory device, more particularly to a semiconductor memory device in which data are programmed by hot electron injection.

2. Description of the Related Art

A semiconductor memory device in which data are programmed by hot electron injection usually has memory cell transistors formed in a p⁻-type substrate, that is, a substrate made of a comparatively lightly doped p-type semiconductor material. To program data into a memory cell transistor, high gate and drain voltages are applied to the transistor and hot electrons generated by the high electric field between the source and drain regions are drawn to the gate electrode by the electric field between the gate electrode and the drain region. The programming operation also generates holes that flow through the semiconductor substrate as a substrate current due to the electric field between the drain region and the semiconductor substrate.

Because the semiconductor substrate has a resistivity of several ohm-centimeters (Ω·cm), the flow of substrate current is accompanied by a voltage drop, the effect of which is to elevate the substrate potential in the vicinity of the source and drain regions, degrading the programming characteristics of the device.

In a solution to this problem proposed by Wada et al. in Japanese Patent Application Publication No. H09-260505, a p⁻-type semiconductor layer (for example, an epitaxial layer) is deposited on a more heavily doped p⁺-type semiconductor substrate, and the memory cell transistors are formed in the p⁻-type semiconductor layer. With this structure, the thickness of the p⁻-type semiconductor material is reduced and most of the substrate current is conducted by the p⁺-type substrate, which offers less resistance than the p⁻-type layer. If the resistance of the p⁺-type substrate is sufficiently low the voltage drop due to the substrate current is determined mainly by the current path length across the thickness of the p⁻-type layer. If the p⁻-type layer is sufficiently thin, the voltage drop can be reduced to a value such that the substrate potential in the neighborhood of the source and drain regions does not rise significantly.

The p⁻-type semiconductor layer must be thick enough, however, to accommodate the n-wells in which p-channel transistors are formed in peripheral circuit regions, leaving at least a certain distance between the bottoms of the n-wells and the p⁺-type semiconductor substrate so that current flow in the p⁺-type substrate will not adversely affect the operation of the p-channel transistors. This requirement constrains the thinness of the p⁻-type layer and sets a lower limit on the distance between the p⁺-type substrate and the source and drain regions of the memory cell transistors.

Accordingly, it has not been possible to reduce the thickness of the p⁻-type semiconductor layer below the memory cell transistors sufficiently to eliminate the rise in the substrate potential in the vicinity of their source and drain regions, and the problem of degraded programming characteristics remains unsolved.

### SUMMARY OF THE INVENTION

An object of the present invention is to provide a semiconductor memory device in which degradation of programming characteristics of memory cell transistors is prevented without degrading the characteristics of peripheral circuits.

The invention provides a semiconductor memory device in which data are programmed by hot electron injection. The semiconductor memory device has a semiconductor substrate of a first conductivity type, having a first resistivity.

A semiconductor layer of the first conductivity type, having a second resistivity, is disposed on the semiconductor substrate. The second resistivity is higher than the first resistivity.

A memory cell transistor is formed in the semiconductor layer. The memory cell transistor includes a source region, a drain region, a gate insulating layer, and gate electrode.

A diffusion region of the first conductivity type, having a third resistivity, is disposed in the semiconductor layer below the memory cell transistor. The diffusion region is contiguous with the semiconductor substrate and is spaced apart from the memory cell transistor. The third resistivity is lower than the second resistivity.

During programming by hot electron injection, substrate current flows from the part of the semiconductor layer near the source and drain regions of the memory cell transistor through the diffusion region into the semiconductor substrate. In passing through the diffusion region, the substrate current experiences less voltage drop than it would experience if forced to flow through other parts of the semiconductor layer. The reduced voltage drop means a reduced shift in the potential of the semiconductor layer near the source and drain regions of the memory cell transistor. If the diffusion region has a sufficiently low resistivity and is sufficiently close to the memory cell transistor, adverse effects of the substrate current on the hot electron injection process can be avoided.

The semiconductor device may also have a well of a second conductivity type formed in the semiconductor layer and a peripheral circuit transistor formed in the well. The diffusion region formed below the memory cell does not affect the operation of the peripheral circuit transistor because the diffusion region and well are formed in different parts of the semiconductor layer. For the same reason, the presence of the well does not constrain the height of the diffusion region.

### BRIEF DESCRIPTION OF THE DRAWINGS

In the attached drawings:

FIG. 1 is a sectional view of part of a memory device according to the present invention;

FIGS. 2 to 8 illustrate steps in the fabrication of the memory device in FIG. 1; and

FIG. 9 is a sectional diagram illustrating the effect of the invention.

### DETAILED DESCRIPTION OF THE INVENTION

An embodiment of the invention will now be described with reference to the attached drawings, in which like elements are indicated by like reference characters.

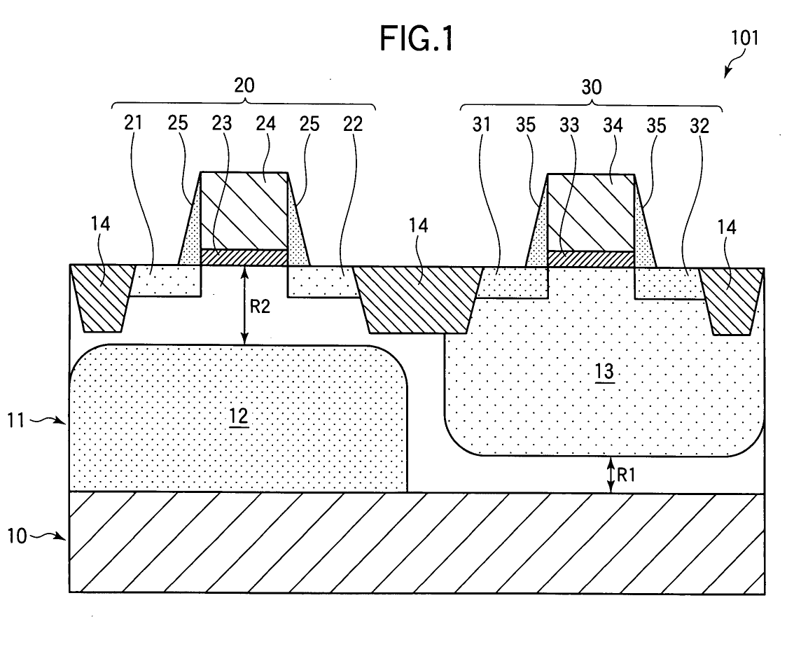

Referring to FIG. 1, the embodiment is a semiconductor memory device 101 including a memory cell transistor 20 and a peripheral circuit transistor 30. Although the semiconductor memory device 101 includes an array of memory cell transistors 20, only a single memory cell transistor is shown for simplicity. The peripheral circuits of the semiconductor memory device 101 include a plurality of both p-channel metal-oxide-semiconductor (PMOS) transistors and n-channel metal-oxide-semiconductor (NMOS) transistors, which are used for reading and programming data in the memory cells, but only a single PMOS transistor is shown for simplicity. Other necessary structures, such as interlayer dielectric films, contact holes, metal interconnections, and a passivation layer are omitted from FIG. 1 as they are well known.

The elements of the semiconductor memory device 101 that are shown in FIG. 1 include a comparatively heavily doped p-type silicon semiconductor substrate, referred to below as a p⁺ substrate 10. A more lightly doped p-type silicon epitaxial semiconductor layer, referred to below as a p⁻ epitaxial layer 11, is formed on the p⁺ substrate 10. The memory cell transistor 20 is formed in the p⁻ epitaxial layer 11. A comparatively heavily doped p⁺ impurity diffusion region 12 is formed in the p⁻ epitaxial layer 11 below the memory cell transistor 20. The peripheral circuit transistor 30 is formed in an n-type well or n-well 13 formed in the p⁻ epitaxial layer 11.

The p-type epitaxial layer, diffusion region, and substrate are said to be of the first conductive type. The n-well 13 is said to be of the second conductivity type.

The p⁺ substrate 10 has a resistivity of, for example, 0.001 to 0.002 Ω·cm. The p⁻ epitaxial layer 11 has a higher resistivity of, for example, several ohm-centimeters, typically, 1 to 10 Ω·cm.

The p⁻ epitaxial layer 11 has a thickness of, for example, three to ten micrometers (3 to 10 μm, typically about 4.5 μm). The bottom of the n-well 13 is separated from the p⁺ substrate 10 by a distance R1 of, for example, 0.2 to 2 μm measured in the thickness direction of the p⁻ epitaxial layer 11. This separation R1 is adequate to prevent the peripheral circuit transistor 30 from being affected by substrate current flow in the p⁺ substrate 10.

The memory cell transistor 20 and the peripheral circuit transistor 30 are mutually isolated by an isolation trench 14 formed in the p⁻ epitaxial layer 11.

The memory cell transistor 20 has a well known structure including, for example, a source region 21, a drain region 22, a gate insulating layer 23, a gate electrode 24, and sidewalls 25. The source region 21 and the drain region 22 are comparatively heavily doped n-type (n⁺) regions formed by diffusion of an n-type impurity into the surface of the p⁻ epitaxial layer 11. The gate insulating layer 23 and the gate electrode 24 are formed on the surface of the p⁻ epitaxial layer 11 between the source region 21 and the drain region 22. The channel region of the memory cell transistor 20 is disposed in the p⁻ epitaxial layer 11 immediately below the gate insulating layer 23, which insulates the p⁻ epitaxial layer 11 from the gate electrode 24. The sidewalls 25 cover the sides of the gate insulating layer 23 and the gate electrode 24.

The peripheral circuit transistor 30 has a similar structure including, for example, a source region 31, a drain region 32, a gate insulating layer 33, a gate electrode 34, and sidewalls 35. The source region 31 and the drain region 32 are p⁺ regions formed by diffusion of a p-type impurity into the surface of the n-well 13. The gate insulating layer 33 and the gate electrode 34 are formed on the surface of the n-well 13, between the source region 31 and the drain region 32. The sidewalls 35 cover the sides of the gate insulating layer 33 and the gate electrode 34.

The p⁺ impurity diffusion region 12 is disposed in the p⁻ epitaxial layer 11 below the memory cell transistor 20 at such a depth as to be contiguous with the p⁺ substrate 10. The p⁺ impurity diffusion region 12 has a lower resistivity than the p⁻ epitaxial layer 11. The resistivity of the p⁺ impurity diffusion region 12 is preferably comparable to or higher than the resistivity of the p⁺ substrate 10. For example, the p⁺ impurity diffusion region 12 may have a resistivity of 0.01 to 0.1 Ω·cm. Taken together, the p⁺ impurity diffusion region 12 and p⁺ substrate 10 form a continuous region having a lower resistance than the p⁻ epitaxial layer 11.

The p⁺ impurity diffusion region 12 is separated from the memory cell transistor 20, including the source region 21, the drain region 22, and the channel region therebetween, by a distance R2 measured in the thickness direction of the p⁻ epitaxial layer 11 from the gate insulating layer 23 of the memory cell transistor 20 to the p⁺ impurity diffusion region 12, that is, from the surface of the p⁻ epitaxial layer 11 to the p⁺ impurity diffusion region 12. This distance R2 is preferably from 1.5 to 4.5 μm. Since the source region 21, drain region 22, and channel region of the memory cell transistor 20 occupy a thickness of about 1 μm at the top of the p⁻ epitaxial layer 11, a separation R2 within the above range prevents the channel current, junction breakdown voltage, and other characteristics of the memory cell transistor 20 from being affected by the p⁺ impurity diffusion region 12.

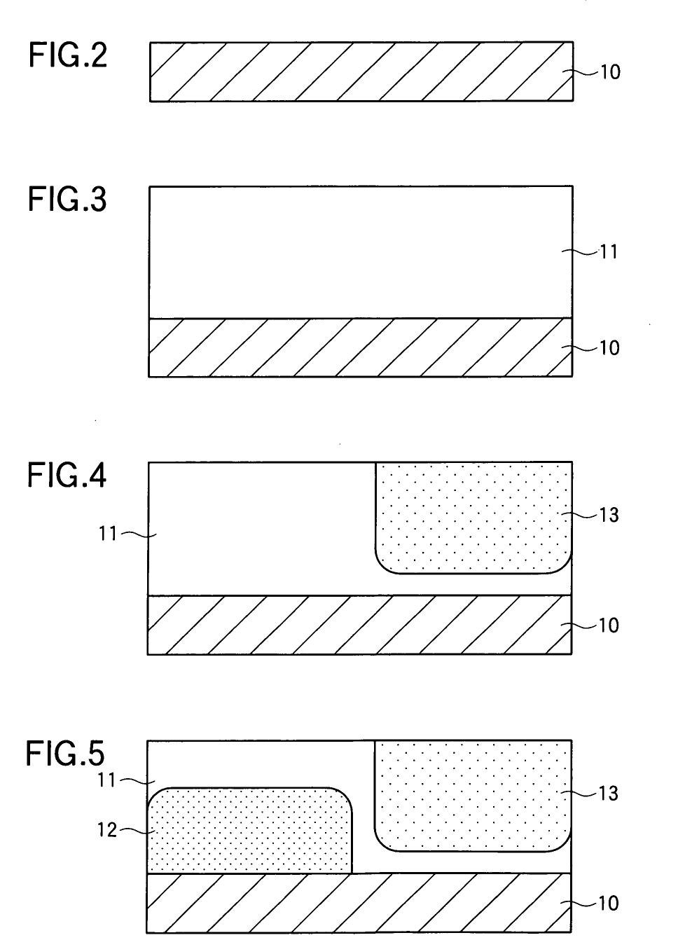

Next, an exemplary method of fabricating the semiconductor memory device 101 will be described with reference to FIGS. 2 to 8.

First the p⁺ substrate 10 is prepared as shown in FIG. 2.

Next, as shown in FIG. 3, the p⁻ epitaxial layer 11 is formed on the surface of the p⁺ substrate 10 by a method such as, for example, chemical vapor deposition (CVD), using well-known epitaxial growth apparatus.

Next a resist is applied to the surface of the p⁻ epitaxial layer 11 and patterned by photolithography to form a first ion implantation mask (not shown) with an opening in a region in which the peripheral circuit transistor 30 will be formed. The n-well 13 shown in FIG. 4 is formed by implanting n-type ions through the first ion implantation mask to a predetermined depth in the p⁻ epitaxial layer 11. The implantation depth is less than the thickness of the p⁻ epitaxial layer 11, so the bottom of the n-well 13 does not reach the p⁺ substrate 10. An annealing process is then performed to activate the implanted ions. The n-type ion implantation and annealing process are performed under conventional conditions, which will not be described to avoid obscuring the invention with needless detail.

Next the first ion implantation mask is removed and the surface of the p⁻ epitaxial layer 11 is planarized by chemical mechanical polishing (CMP). A new resist is applied to the surface of the p⁻ epitaxial layer 11 and patterned by photolithography to form a second ion implantation mask (not shown) with an opening in a region in which the memory cell transistor 20 will be formed. The p⁺ impurity diffusion region 12 shown in FIG. 5 is formed by implanting p-type ions through the second mask to a predetermined depth in the p⁻ epitaxial layer 11, allowing the bottom of the p⁺ impurity diffusion region 12 to reach the p⁺ substrate 10, with an implantation energy such that the p⁺ impurity diffusion region 12 is entirely buried in the p⁻ epitaxial layer 11. An annealing process is then performed at, for example, a temperature of 1050° C. for six hours to activate the implanted ions.

In the p-type ion implantation, boron (B) ions may be implanted at, for example, an acceleration energy of about 1.5 keV and a dose of 10¹⁴ to 10¹⁶ cm⁻².

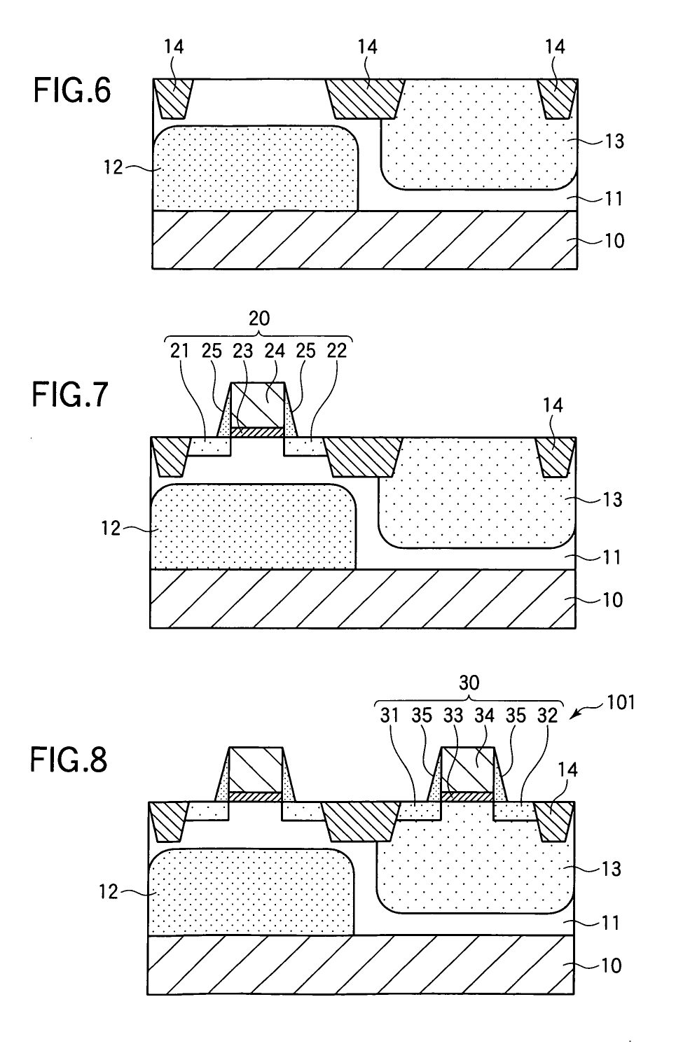

Next the second ion implantation mask (not shown) is removed and the surface of the p⁻ epitaxial layer 11 is planarized by CMP. Then another resist is applied to the surface of the p⁻ epitaxial layer 11 and patterned by photolithography to form an etching mask (not shown) with openings in predetermined locations. An etching process is carried out with this mask to form trenches for shallow trench isolation (STI). The trenches extend to a predetermined depth in the thickness direction of the p⁻ epitaxial layer 11 and surround each transistor formation region. The trenches are filled with an oxide material, for example, to form the isolation trenches 14 shown in FIG. 6.

Referring to FIG. 7, next the memory cell transistor 20 is created. First the gate insulating layer 23 and gate electrode 24 are formed on the p⁻ epitaxial layer 11 in a region surrounded by the isolation trenches 14, above the p⁺ impurity diffusion region 12 and external to the n-well 13. The source region 21 and drain region 22 are then formed by implanting n-type ions into surface regions of the p⁻ epitaxial layer 11 on mutually opposite sides of the gate insulating layer 23 and gate electrode 24. Finally, the sidewalls 25 are formed on the sides of the gate insulating layer 23 and gate electrode 24.

The method of forming the memory cell transistor 20 is not limited to this method; other known methods may be employed.

Referring to FIG. 8, next the peripheral circuit transistor 30 is created. First the gate insulating layer 33 and gate electrode 34 are formed in a region of the n-well 13 surrounded by the isolation trenches 14. The source region 31 and the drain region 32 are then formed by implanting p-type ions into surface regions of the n-well 13 on mutually opposite sides of the gate insulating layer 33 and gate electrode 34. Finally, the sidewalls 35 are formed on the sides of the gate insulating layer 33 and gate electrode 34.

The method of forming the peripheral circuit transistor 30 is not limited to this method; other known methods may be employed.

After these steps, other elements (not shown) such as, for example, interlayer dielectric films, contact holes, metal interconnections, and a passivation layer are formed to complete the semiconductor memory device 101.

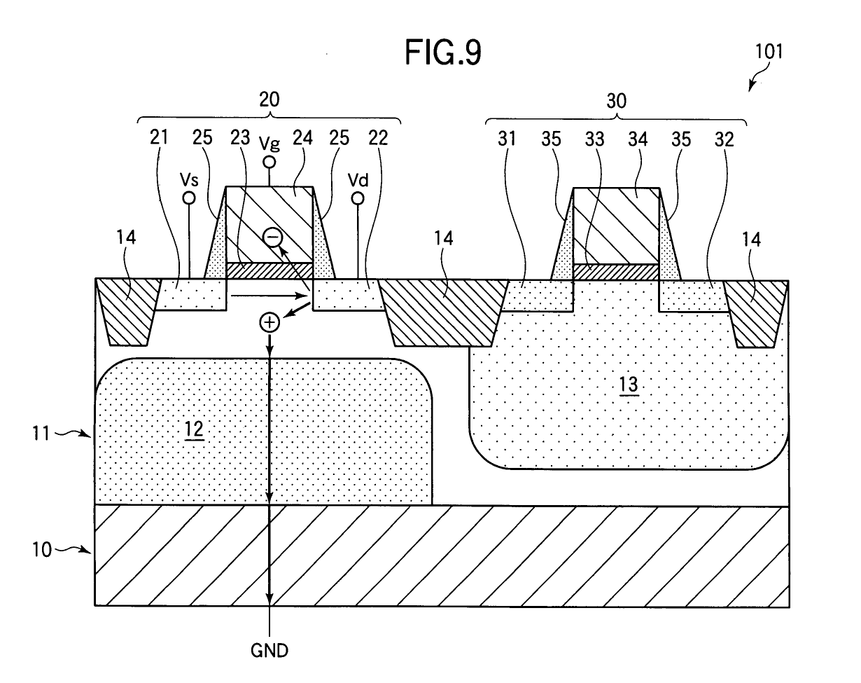

The effect of the invention will now be described with reference to FIG. 9.

Data are programmed into the memory cell transistor 20 by creating a strong electric field between the source region 21 and the drain region 22 to generate hot electrons, and creating a strong electric field between the gate electrode 24 and the drain region 22 to draw the hot electrons into the gate electrode 24. These electric fields are created by applying a suitable source voltage Vs, gate voltage Vg, and drain voltage Vd to the source region 21, gate electrode 24, and drain region 22, respectively. During the programming operation, the p⁺ substrate 10 is grounded, as indicated by the GND notation in FIG. 9. The strong electric fields also generate holes, which are drawn to ground through the p⁻ epitaxial layer 11, the p⁺ impurity diffusion region 12, and the p⁺ substrate 10 as substrate current, due to the electric field between the drain region 22 and the p⁺ substrate 10.

The substrate current undergoes a voltage drop due to the resistance of the p⁻ epitaxial layer 11, p⁺ impurity diffusion region 12, and p⁺ substrate 10, creating a potential difference between the grounded bottom part of the p⁺ substrate 10 and the upper part of the p⁻ epitaxial layer 11 near the source region 21 and drain region 22 of the memory cell transistor 20, thereby raising the potential of the upper part of the p⁻ epitaxial layer 11 above the ground level. This rise in the potential of the p⁻ epitaxial layer 11 near the source and drain of the memory cell transistor 20 counteracts the electric fields created by the source, gate, and drain voltages, reducing the efficiency of hot electron injection into the gate electrode 24.

In the present embodiment, however, the voltage drop and resultant potential shift are small because most of the substrate current path lies in the p⁺ substrate 10 and p⁺ impurity diffusion region 12, which have comparatively low resistivity. Only a very short part of the substrate current path lies in the p⁻ epitaxial layer 11, which has a higher resistivity. The result is that the potential shift created by the substrate current is too small to affect the hot electron injection operation significantly.

Without the novel p⁺ impurity diffusion region 12, much more of the substrate current path would lie in the p⁻ epitaxial layer 11, the voltage drop and resulting potential shift would be greater, and hot electron injection would be significantly affected.

The p⁺ impurity diffusion region 12 is separated from the adjacent n-well 13 by a distance comparable to the separation between the n-well 13 and the p⁺ substrate 10. Accordingly, the p⁺ impurity diffusion region 12 does not significantly affect the n-well 13 or the operation of the peripheral circuit transistor 30.

Although the drawings show hot electrons being injected into the gate electrode of the memory cell transistor, the invention is also applicable to semiconductor memory devices in which hot electrons are injected into the sidewalls, or into a floating gate electrode disposed adjacent to the gate electrode or between the gate electrode and the gate insulating layer.

The invention is also applicable to substrate hot electron injection.

Those skilled in the art will recognize that further variations are possible within the scope of the invention, which is defined in the appended claims.

What is claimed is:

1. A semiconductor memory device in which data are programmed by hot electron injection, the semiconductor memory device comprising:
a semiconductor substrate of a first conductivity type, having a first resistivity;
a semiconductor layer disposed on the semiconductor substrate, the semiconductor layer being of the first conductivity type and having a second resistivity higher than the first resistivity;
a memory cell transistor formed in the semiconductor layer, the memory cell transistor including a source region, a drain region, a gate insulating layer, and a gate electrode, the gate insulating layer and the gate electrode being disposed between the source region and the drain region, the gate insulating layer insulating the gate electrode from the semiconductor layer; and
a diffusion region disposed in the semiconductor layer below the memory cell transistor, the diffusion region being contiguous with the semiconductor substrate and spaced apart from the memory cell transistor, the diffusion region having a third resistivity lower than the second resistivity.

2. The semiconductor memory device of claim 1, wherein the diffusion region is separated from the gate insulating layer of the memory cell transistor by a distance of at most 4.5 micrometers.

3. The semiconductor memory device of claim 1, wherein the diffusion region is separated from the gate insulating layer of the memory cell transistor by a distance of at least 1.5 micrometers.

4. The semiconductor memory device of claim 1, wherein the third resistivity is higher than the first resistivity.

5. The semiconductor memory device of claim 1, wherein the third resistivity is substantially equal to the first resistivity.

6. The semiconductor memory device of claim 1, wherein the first resistivity is at most 0.002 ohm-centimeters.

7. The semiconductor memory device of claim 1, wherein the first resistivity is at least 0.001 ohm-centimeters.

8. The semiconductor memory device of claim 1, wherein the second resistivity is at least one ohm-centimeter.

9. The semiconductor memory device of claim 1, wherein the second resistivity is at most ten ohm-centimeters.

10. The semiconductor memory device of claim 1, wherein the third resistivity is at most 0.1 ohm-centimeters.

11. The semiconductor memory device of claim 1, wherein the third resistivity is at least 0.01 ohm-centimeters.

12. The semiconductor memory device of claim 1, wherein the semiconductor layer has a thickness of at least three micrometers.

13. The semiconductor memory device of claim 1, wherein the semiconductor layer has a thickness of at most ten micrometers.

14. The semiconductor memory device of claim 1, further comprising:
a well of a second conductive type formed in the semiconductor layer, separated from the semiconductor substrate, the memory cell transistor, and the diffusion region; and
a peripheral circuit transistor formed in the well.
